(19) United States
(12) Patent Application Publication
(10) Pub. No.: US 2018/0173366 A1
(43) Pub. Date: Jun. 21, 2018

(54) APPARATUS AND METHOD FOR CAPACITANCE CALIBRATION, AND TOUCH DISPLAY SCREEN

(71) Applicants: BOE TECHNOLOGY GROUP CO., LTD., Beijing (CN); HEFEI XINSHENG OPTOELECTRONICS TECHNOLOGY CO., LTD., Hefei, Anhui (CN)

(72) Inventors: Yanping ZHANG, Beijing (CN); Dayu ZHANG, Beijing (CN)

(21) Appl. No.: 15/553,400

(22) PCT Filed: Feb. 15, 2017
(86) PCT No.: PCT/CN2017/073557

§ 371 Date: Aug. 24, 2017

(30) Foreign Application Priority Data
May 30, 2016 (CN) 201610371446.4

(51) Int. Cl. G06F 3/041; G01R 27/26; H04N 1/00; G06F 3/0488

(52) U.S. Cl. CPC G06F 3/0418; G06F 3/0488; H04N 1/00411; G01R 27/2605

(57) ABSTRACT

Disclosed is a capacitance calibration apparatus including a detection unit configured to measure a capacitance of a coupling capacitor in each of a plurality of non-touch time periods, and a calibration unit configured to, at each measurement, calibrate a base capacitance of the coupling capacitor based on the measured capacitance. Also disclosed are a capacitance calibration method and a touch display device.

### CROSS-REFERENCE TO RELATED APPLICATIONS

The present application is the U.S. national phase entry of PCT/CN2017/073557, with an international filing date of Feb. 15, 2017, which claims the benefit of Chinese Patent Application No. 201610371446.4, filed on May 30, 2016, the entire disclosures of which are incorporated herein by reference.

### TECHNICAL FIELD

The present disclosure relates to the field of touch display technology, and more particularly to an apparatus and method for capacitance calibration, and a touch display device.

### BACKGROUND

A projection capacitive touch display panel is provided with an X-axis electrode layer and a Y-axis electrode layer stacked on top of each other and insulated from each other. FIG. 1 schematically shows an arrangement of the X-axis electrode layer and the Y-axis electrode layer in the projection capacitive touch display panel. A plurality of X-axis touch electrodes 10 are arranged in an array in the X-axis electrode layer, with the X-axis touch electrodes of the same row being connected in series to form a respective touch electrode row. A plurality of Y-axis touch electrodes 20 are arranged in an array in the Y-axis electrode layer, with Y-axis touch electrodes of the same column being connected in series to form a respective touch electrode column.

When no conductive object is in contact with the touch display panel, coupling capacitors C_{M} are formed between the touch electrode rows and the touch electrode columns (e.g., at their intersections), and the capacitance of the capacitor C_{M} is referred to as the base capacitance. When a finger or other conductive object touches the touch display panel, the capacitance of the coupling capacitor C_{M} will change. The touch position of the finger or other conductive object on the touch display panel can be determined by measuring the change in the capacitance of each coupling capacitor C_{M}.

In the prior art, the capacitance of the coupling capacitor is measured only upon powering up of the touch display panel and the measurement result is set as the base capacitance of the coupling capacitor. The base capacitance is not updated thereafter. However, the base capacitance may change over time or depending on the picture displayed on the touch display panel. The change in the base capacitance may cause false recognition of touch operations, such as false positives.

### SUMMARY

Embodiments of the present disclosure provide an apparatus and method for capacitance calibration and a touch display device, which may alleviate, mitigate or eliminate at least one of the above-mentioned problems.

According to an aspect of the present disclosure, an apparatus is provided for calibrating a base capacitance of a touch display panel. The touch display panel is provided with a first electrode layer and a second electrode layer stacked on top of each other and insulated from each other. The first electrode layer comprises at least one row of touch electrodes. The second electrode layer comprises at least one column of touch electrodes. The at least one row of touch electrodes and the at least one column of touch electrodes form at least one coupling capacitor. The apparatus comprises a detection unit configured to measure a capacitance of the coupling capacitor in each of a plurality of non-touch time periods, and a calibration unit configured to calibrate the base capacitance of the coupling capacitor at each measurement based on the measured capacitance.

In some embodiments, the plurality of non-touch time periods are periodic.

In some embodiments, each of the plurality of non-touch time periods is inserted between a corresponding display time period and a corresponding touch time period that are allocated for the touch display panel.

In some embodiments, the plurality of non-touch time periods are aperiodic.

In some embodiments, the detection unit comprises a charge/discharge module configured to charge the touch electrodes until a voltage across the coupling capacitor reaches a target value, and then to discharge the coupling capacitor to detect an amount of charge stored in the coupling capacitor, and a capacitance calculation module configured to calculate the capacitance of the coupling capacitor based on the target value and the amount of charge.

In some embodiments, the apparatus further comprises a comparison unit configured to compare the measured capacitance with an original capacitance at each measurement. The calibration unit is further configured to set the base capacitance to the measured capacitance in response to the comparison unit indicating that an absolute value of a difference between the measured capacitance and the original capacitance is greater than a threshold.

According to another aspect of the present disclosure, a method is provided for calibrating a base capacitance of a touch display panel. The touch display panel is provided with a first electrode layer and a second electrode layer stacked on top of each other and insulated from each other. The first electrode layer comprises at least one row of touch electrodes. The second electrode layer comprises at least one column of touch electrodes. The at least one row of touch electrodes and the at least one column of touch electrodes form at least one coupling capacitor. The method comprises measuring a capacitance of the coupling capacitor in each of a plurality of non-touch time periods, and calibrating the base capacitance of the coupling capacitor at each measurement based on the measured capacitance.

In some embodiments, the plurality of non-touch time periods are periodic.

In some embodiments, each of the plurality of non-touch time periods is inserted between a corresponding display time period and a corresponding touch time period that are allocated for the touch display panel.

In some embodiments, the plurality of non-touch time periods are aperiodic.

In some embodiments, the step of measuring comprises charging the touch electrodes until a voltage across the coupling capacitor reaches a target value, discharging the coupling capacitor to detect an amount of charge stored in the coupling capacitor, and calculating the capacitance of the coupling capacitor based on the target value and the amount of charge.

In some embodiments, the step of calibrating comprises comparing the measured capacitance with an original capacitance, and setting the base capacitance to the measured capacitance in response to an absolute value of a difference between the measured capacitance and the original capacitance being greater than a threshold.

According to yet another aspect of the present disclosure, a touch display device is provided which comprises a touch display panel provided with a first electrode layer and a second electrode layer stacked on top of each other and insulated from each other, the first electrode layer comprising at least one row of touch electrodes, the second electrode layer comprising at least one column of touch electrodes, the at least one row of touch electrodes and the at least one column of touch electrodes forming at least one coupling capacitor, a detection unit configured to measure a capacitance of the coupling capacitor in each of a plurality of non-touch time periods, and a calibration unit configured to calibrate a base capacitance of the coupling capacitor at each measurement based on the measured capacitance.

These and other aspects of the present disclosure will be apparent from and elucidated with reference to the embodiment(s) described hereinafter.

### BRIEF DESCRIPTION OF THE DRAWINGS

FIG. 1 schematically shows an arrangement of an X-axis electrode layer and a Y-axis electrode layer in a projection capacitive touch display panel;

FIG. 2 is a block diagram of a capacitance calibration apparatus according to an embodiment of the present disclosure;

FIG. 3 is a block diagram of an implementation of the capacitance calibration apparatus according to an embodiment of the present disclosure;

FIG. 4 is a block diagram of another implementation of the capacitance calibration apparatus according to an embodiment of the present disclosure;

FIG. 5 is a flow chart of a capacitance calibration method according to an embodiment of the present disclosure; and

FIG. 6 is a flow chart illustrating an implementation of the measurement of the capacitance in the method of FIG. 5.

### DETAILED DESCRIPTION

Embodiments of the present disclosure will now be described in detail with reference to the accompanying drawings. Apparently, the embodiments described are merely illustrative and not restrictive. All other embodiments derived from the embodiments of the present disclosure by one of ordinary skill in the art without making any inventive effort fall within the scope of the present disclosure.

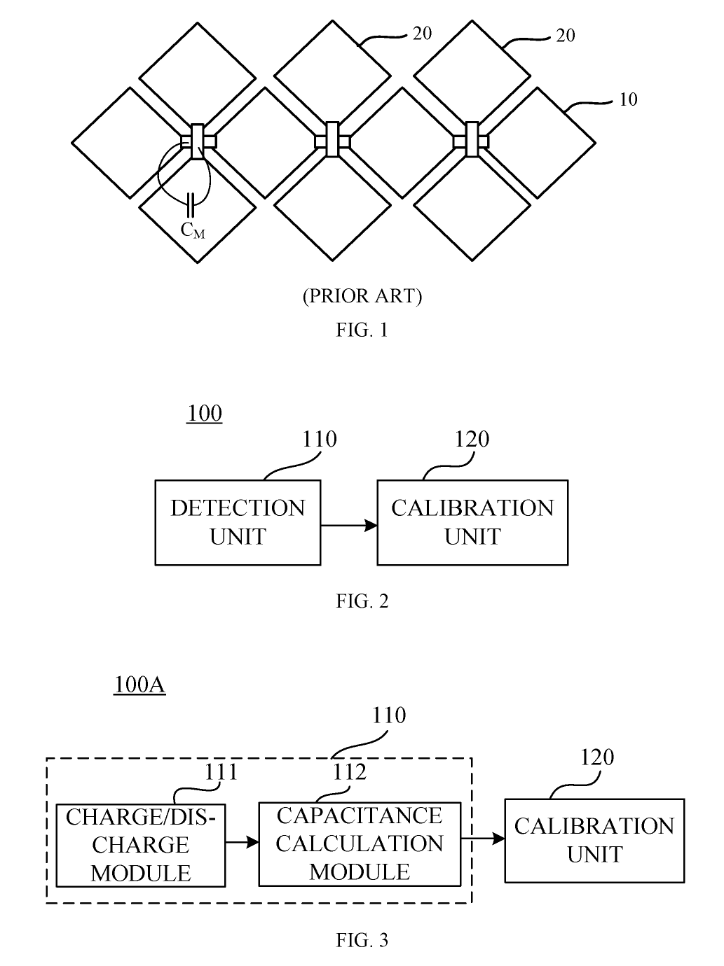

FIG. 2 is a block diagram of a capacitance calibration apparatus 100 according to an embodiment of the present disclosure. The capacitance calibration device 100 may be a component of a touch display panel, or a stand-alone apparatus operably coupled to the touch display panel. The touch display panel is provided with a first electrode layer and a second electrode layer stacked on top of each other and insulated from each other. The first electrode layer comprises at least one row of touch electrodes. The second electrode layer comprises at least one column of touch electrodes. The at least one row of touch electrodes and the at least one column of touch electrodes form at least one coupling capacitor. An example arrangement of the touch electrodes in the touch display panel is shown in FIG. 1, and is not described in detail here.

Referring to FIG. 2, the capacitance calibration apparatus 100 includes a detection unit 110 and a calibration unit 120. The detection unit 110 is configured to measure a capacitance of the coupling capacitor in each of a plurality of non-touch time periods. The calibration unit 120 is configured to calibrate a base capacitance of the coupling capacitor at each measurement based on the measured capacitance.

In this way, the base capacitance is calibrated when the touch display panel is in use, so that erroneous recognition of touch operations due to a change in the base capacitance is reduced, thereby improving the accuracy of the touch operations.

The non-touch time period as described herein refers to a period of time that is not allocated to a touch display panel for detecting a touch operation. In other words, the non-touch time period does not overlap with a touch time period.

The plurality of non-touch time periods can be periodic. In some embodiments, each non-touch time period is inserted between a display time period and a touch time period that are allocated for the touch display panel. For example, the non-touch time period may be inserted after the display time period and before the touch time period. In this way, the base capacitance is updated before each touch time period, so that the accuracy of the recognition of the touch operation is improved. Other embodiments are possible. For example, the non-touch time period may overlap with the display time period. For another example, the detection and calibration of the base capacitance may be performed at a fixed interval without the need to be performed before each touch time period. Alternatively, the plurality of non-touch time periods may also be aperiodic.

FIG. 3 is a block diagram of an implementation 100A of the capacitance calibration apparatus according to an embodiment of the present disclosure.

Referring to FIG. 3, the capacitance detection unit 110 includes a charge/discharge module 111 and a capacitance calculation module 112. The charge/discharge module 111 is configured to charge the touch electrodes until a voltage across the coupling capacitor reaches a target value, and then to detect an amount of charge stored in the coupling capacitor by discharging the coupling capacitor. The capacitance calculation module 112 is configured to calculate the capacitance of the coupling capacitor based on the target value and the amount of charge.

In this implementation, the detection of the amount of charge may be based on the formula Q=I×t, and the detection of the capacitance may be based on the formula C=Q/U, where Q is the amount of charge stored by the coupling capacitor, I is the current generated by discharging the coupling capacitor, t is the discharge time, U is the voltage across the coupling capacitor, and C is the capacitance of the coupling capacitor. The implementation of the capacitance detection unit 110 is however not so limited.

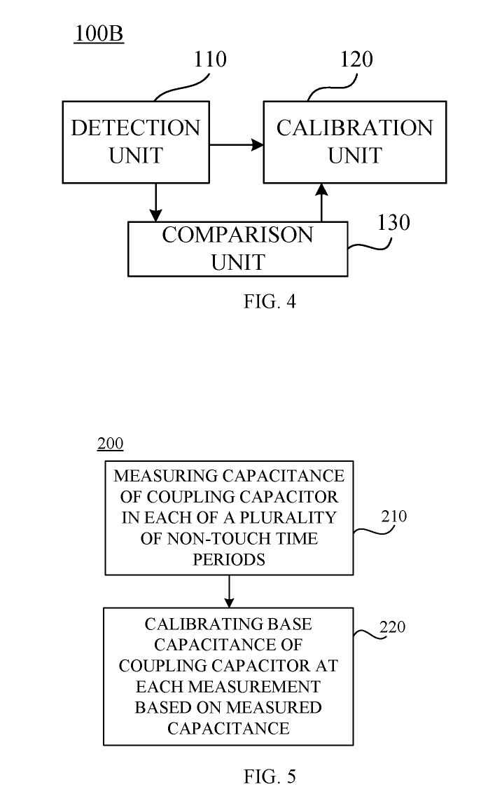

FIG. 4 is a block diagram of another embodiment 100B of the capacitance calibration apparatus according to an embodiment of the present disclosure.

Referring to FIG. 4, the capacitance calibration apparatus 100B further includes a comparison unit 130 as compared with the capacitance calibration apparatus 100 shown in FIG. 2. The comparison unit 130 is configured to compare the measured capacitance with an original capacitance at each measurement. The calibration unit 120 is further configured to set the base capacitance to the measured capacitance in response to the comparison by the comparison unit 130 indicating that an absolute value of a difference between the measured capacitance and the original capacitance is greater than a threshold. The original capacitance, as used herein, may refer to the capacitance of the coupling capacitor measured by the detection unit 110 at the very beginning (in the first non-touch time period).

In this implementation, the base capacitance is set to the measured capacitance only when the absolute value of the difference between the measured capacitance and the original capacitance is greater than the threshold. This can save the processing resources of the system.

FIG. 5 is a flow chart of a capacitance calibration method 200 according to an embodiment of the present disclosure. The method 200 may be used to calibrate a base capacitance of the touch display panel. The touch display panel is provided with a first electrode layer and a second electrode layer stacked on top of each other and insulated from each other. The first electrode layer comprises at least one row of touch electrodes. The second electrode layer comprises at least one column of touch electrodes. The at least one row of touch electrodes and the at least one column of touch electrodes form at least one coupling capacitor. An example arrangement of the touch electrodes in the touch display panel is shown in FIG. 1, and is not described in detail here.

Referring to FIG. 5, the method 200 includes the following steps.

At step 210, the capacitance of the coupling capacitor is measured in each of a plurality of non-touch time periods.

At step 220, the base capacitance of the coupling capacitor is calibrated at each measurement based on the measured capacitance.

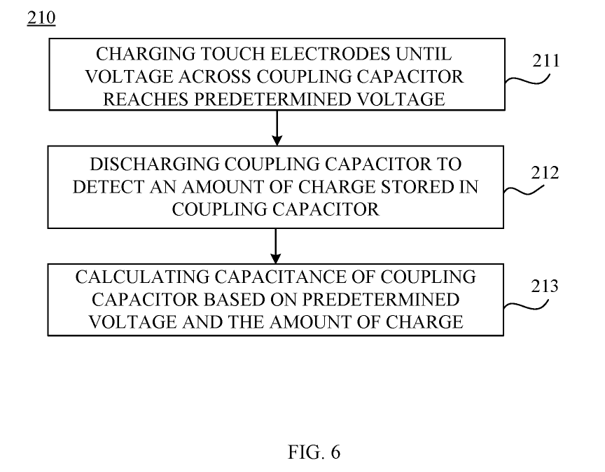

FIG. 6 is a flow chart illustrating an implementation of the measurement of the capacitance in the method 200 of FIG. 5.

The measurement 210 of the capacitance of the coupling capacitor may specifically include the following steps.

At step 211, the touch electrodes are charged until a voltage across the coupling capacitor reaches a target value.

At step 212, the coupling capacitor is discharged to detect an amount of charge stored by the coupling capacitor.

At step 213, the capacitance of the coupling capacitor is calculated based on the target value and the amount of charge.

In addition, in some embodiments, the calibration 220 of the base capacitance may include comparing the measured capacitance with an original capacitance, and setting the base capacitance to the measured capacitance in response to an absolute value of a difference between the measured capacitance and the original capacitance being greater than a threshold.

The above method embodiments have the same advantages as the apparatus embodiments described with respect to FIGS. 2-4, which are not described in detail here.

It will be appreciated that the various illustrative logical blocks, modules, and circuits described in connection with the embodiments disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The foregoing are specific embodiments of the present disclosure. Various modifications and variations can be made by one of ordinary skill in the art without departing from the spirit and essence of the disclosure, and such modifications and variations are intended to be encompassed within the scope of the present disclosure.

1. An apparatus for calibrating a base capacitance of a touch display panel, the touch display panel being provided with a first electrode layer and a second electrode layer stacked on top of each other and insulated from each other, the first electrode layer comprising at least one row of touch electrodes, the second electrode layer comprising at least one column of touch electrodes, the at least one row of touch electrodes and the at least one column of touch electrodes forming at least one coupling capacitor, the apparatus comprising:
a detection unit configured to measure a capacitance of the coupling capacitor in each of a plurality of non-touch time periods; and
a calibration unit configured to calibrate the base capacitance of the coupling capacitor at each measurement based on the measured capacitance.

2. The apparatus of claim 1, wherein the plurality of non-touch time periods are periodic.

3. The apparatus of claim 2, wherein each of the plurality of non-touch time periods is inserted between a corresponding display time period and a corresponding touch time period that are allocated for the touch display panel.

4. The apparatus of claim 1, wherein the plurality of non-touch time periods are aperiodic.

5. The apparatus of claim 1, wherein the detection unit comprises:
a charge/discharge module configured to charge the touch electrodes until a voltage across the coupling capacitor reaches a target value, and then to discharge the coupling capacitor to detect an amount of charge stored in the coupling capacitor; and
a capacitance calculation module configured to calculate the capacitance of the coupling capacitor based on the target value and the amount of charge.

6. The apparatus of claim 1, further comprising a comparison unit configured to compare the measured capacitance with an original capacitance at each measurement, wherein the calibration unit is further configured to set the base capacitance to the measured capacitance in response to the comparison unit indicating that an absolute value of a difference between the measured capacitance and the original capacitance is greater than a threshold.

7. A method for calibrating a base capacitance of a touch display panel, the touch display panel being provided with a first electrode layer and a second electrode layer stacked on top of each other and insulated from each other, the first electrode layer comprising at least one row of touch electrodes, the second electrode layer comprising at least one column of touch electrodes, the at least one row of touch electrodes and the at least one column of touch electrodes forming at least one coupling capacitor, the method comprising:
measuring a capacitance of the coupling capacitor in each of a plurality of non-touch time periods; and
calibrating the base capacitance of the coupling capacitor at each measurement based on the measured capacitance.

8. The method of claim 7, wherein the plurality of non-touch time periods are periodic.

9. The method of claim 8, wherein each of the plurality of non-touch time periods is inserted between a corresponding display time period and a corresponding touch time period that are allocated for the touch display panel.

10. The method of claim 7, wherein the plurality of non-touch time periods are aperiodic.

11. The method of claim 7, wherein the step of measuring comprises:
charging the touch electrodes until a voltage across the coupling capacitor reaches a target value;
discharging the coupling capacitor to detect an amount of charge stored in the coupling capacitor; and
calculating the capacitance of the coupling capacitor based on the target value and the amount of charge.

12. The method of claim 7, wherein the step of calibrating comprises:
comparing the measured capacitance with an original capacitance; and
setting the base capacitance to the measured capacitance in response to an absolute value of a difference between the measured capacitance and the original capacitance being greater than a threshold.

13. A touch display device, comprising:
a touch display panel provided with a first electrode layer and a second electrode layer stacked on top of each other and insulated from each other, the first electrode layer comprising at least one row of touch electrodes, the second electrode layer comprising at least one column of touch electrodes, the at least one row of touch electrodes and the at least one column of touch electrodes forming at least one coupling capacitor;
a detection unit configured to measure a capacitance of the coupling capacitor in each of a plurality of non-touch time periods; and
a calibration unit configured to calibrate a base capacitance of the coupling capacitor at each measurement based on the measured capacitance.

14. The touch display device of claim 13, wherein the plurality of non-touch time periods are periodic.

15. The touch display device of claim 14, wherein each of the plurality of non-touch time periods is inserted between a corresponding display time period and a corresponding touch time period that are allocated for the touch display panel.

16. The touch display device of claim 13, wherein the plurality of non-touch time periods are aperiodic.

17. The touch display device of claim 13, wherein the detection unit comprises:
a charge/discharge module configured to charge the touch electrodes until a voltage across the coupling capacitor reaches a target value, and then to discharge the coupling capacitor to detect an amount of charge stored in the coupling capacitor; and
a capacitance calculation module configured to calculate the capacitance of the coupling capacitor based on the target value and the amount of charge.

18. The touch display device of claim 13, further comprising a comparison unit configured to compare the measured capacitance with an original capacitance at each measurement, wherein the calibration unit is further configured to set the base capacitance to the measured capacitance in response to the comparison unit indicating that an absolute value of a difference between the measured capacitance and the original capacitance is greater than a threshold.

19. The touch display device of claim 14, further comprising a comparison unit configured to compare the measured capacitance with an original capacitance at each measurement, wherein the calibration unit is further configured to set the base capacitance to the measured capacitance in response to the comparison unit indicating that an absolute value of a difference between the measured capacitance and the original capacitance is greater than a threshold.

20. The touch display device of claim 17, further comprising a comparison unit configured to compare the measured capacitance with an original capacitance at each measurement, wherein the calibration unit is further configured to set the base capacitance to the measured capacitance in response to the comparison unit indicating that an absolute value of a difference between the measured capacitance and the original capacitance is greater than a threshold.
